(19) United States
(12) Patent Application Publication
(10) Pub. No.: US 2003/0230480 A1
(43) Pub. Date: Dec. 18, 2003

(54) Method for depositing sputtered film

(75) Inventors: Akihiko Tsuzumitani, Osaka (JP); Yasutoshi Okuno, Kyoto (JP); Tomonori Okudaira, Tokyo (JP)

Correspondence Address: Jack Q. Lever, Jr., McDERMOTT, WILL & EMERY, 600 Thirteenth Street, N.W., Washington, DC, 20005-3096, US

(73) Assignees: Matsushita Electric Industrial Co., Ltd.; Mitsubishi Denki Kabushiki Kaisha

(21) Appl. No.: 10/460,173

(22) Filed: Jun. 13, 2003

(30) Foreign Application Priority Data
Jun. 13, 2002 (JP) 2002-172462

(51) Int. Cl. C23C 14/32

(52) U.S. Cl. 204/192.12; 204/192.18; 204/192.21; 204/192.22; 204/192.26

(57) ABSTRACT

First, a sputtering process is performed in a chamber using a target containing a plurality of elements to form at a sputtering surface of the target an erosion area different from that formed under a predetermined deposition condition for depositing a desired sputtered film. Next, the sputtered film is deposited on a surface of a sample under the predetermined deposition condition.

### BACKGROUND OF THE INVENTION

The present invention generally relates to methods for depositing a sputtered film using a target containing a plurality of elements.

By introducing an inert gas such as argon (Ar) into a chamber and applying a voltage between a cathode and an anode to cause a glow discharge, positive ions within plasma generated by the glow discharge collide against the surface of a target on the cathode, thus causing a sputtering phenomenon in which target atoms are sputtered.

A sputtering apparatus is a film deposition apparatus for evaporating onto a wafer a sputtered film utilizing this sputtering phenomenon. By using a sputtering apparatus, a material constituting a target can be deposited almost as it is on a wafer; therefore, it becomes possible to deposit thin films having various functions if corresponding targets can be prepared.

In semiconductor fabrication processes, titanium (Ti), tungsten (W) or cobalt (Co), for example, has been conventionally utilized as a wiring material or a gate electrode material. And a sputtering apparatus can be used to perform a semiconductor fabrication process called a reactive sputtering process in which an active gas (reactive gas) introduced into a chamber is allowed to chemically react with sputtered atoms or molecules inside the chamber, thus vaporizing a sputtered film made of, for example, an oxide or a nitride onto a wafer. For example, by adding a nitrogen (N₂) gas to an argon gas and introducing the obtained gas mixture into a chamber to sputter target atoms, a sputtering apparatus can form a sputtered film made of a metal nitride such as titanium nitride (TiN) or titanium tungsten (WN) which functions as a barrier film for a wiring material.

However, in a sputtering apparatus, a vaporized substance might be attached and deposited, for example, on an inner wall of a chamber in addition to a wafer as an object of film deposition, and a part of the vaporized substance deposited on the inner wall might peel off to become a source of particles that contaminate the wafer. Due to this, a normal sputtering apparatus is provided with a replaceable shield member for preventing the deposition of a vaporized substance on a portion of a chamber other than a wafer. The shield member on which a vaporized substance has been deposited is replaced with a new one in predetermined cycles, thus continuously preventing the generation of particles.

The use of the shield member of this type can prevent the deposition of a vaporized substance, for example, on an inner wall of a chamber other than a wafer. However, if the vaporized substance deposited on the shield member is increased in thickness, the vaporized substance peels off to become a source of particles after all. Therefore, the shield member has to be replaced with a new one in short cycles. Since the replacement of the shield member requires time and cost, it is preferable that each replacement cycle is prolonged as long as possible.

A method for reducing particles when depositing a sputtered film by a reactive sputtering process is disclosed in Japanese Unexamined Patent Publication No. 10-130814, for example. The publication discloses a method in which a sputtered film consisting only of a target material is formed on a shield member, and then an object of film deposition (sample) is subjected to a reactive sputtering process, thus depositing a sputtered film made of a compound on the sample. Normally, an alloy containing aluminum (Al), for example, is used to provide a shield member, and if a sputtered film is deposited on the shield member by a reactive sputtering process, it peels off to become a source of particles because the adhesion of the sputtered film formed by a reactive sputtering process to the shield member is poor. Due to this, according to the method disclosed in the publication, a sputtered film consisting only of a target material is deposited on an exposed surface of a shield member before a reactive sputtering process is performed. In this manner, it becomes possible to form on the shield member the sputtered film whose adhesion to the shield member is better than that of a sputtered film formed by a reactive sputtering process, and thus it becomes possible to suppress an increase in the number of particles resulting from film peeling.

Recently, a functional film formed by a sputtering process has been utilized in various fields in addition to a titanium or tungsten-containing compound film functioning as a barrier film for a wiring material. For example, in the field of semiconductor memory devices, studies are conducted on methods for depositing, by a sputtering process, barium strontium titanium oxide (BSTO), lead zirconium titanium oxide (PZTO), or strontium bismuth tantalum oxide (SBTO) as a dielectric film for a capacitor.

A study is also conducted on a method for depositing indium tin oxide (ITO) by a sputtering process. Since ITO not only exhibits high conductivity and high permeability but also allows fine patterning, ITO is used in wide-ranging fields in which it is used to form an electrode for a flat-panel display, an electrode for a solar cell, and an antistatic film.

A sputtering process is also often performed to deposit a compound film made of rare-earth and transition metals used in fabricating magneto-optical recording medium.

Furthermore, in the filed of semiconductor memory devices, miniaturization is advanced, so that semiconductor memory devices in which a node of each cell is 0.2 μm or less are now being developed. Also, in the field of flat-panel displays, further miniaturization of integrated circuit sections and upsizing of display sections are advanced simultaneously. Particularly, in these fields, particles resulting from peeling off of a sputtered film considerably affect the reliability and yield of the product. Therefore, the reduction of the particles is a significant challenge.

Since titanium, tungsten and cobalt consisting of single elements, for example, are single metals, the use of these metals makes it possible to obtain a target that allows easy crystallization and has a high purity. To the contrary, since metal oxides such as BSTO, PZTO, SBTO and ITO each consist of a plurality of elements, the use of these metals cannot help but complicate a method for fabricating a sputtering target.

For example, Japanese Unexamined Patent Publication No.2001-3164 discloses a method for fabricating a target made of BSTO. Specifically, the publication describes a method for fabricating a target that is made of BSTO by sintering powdery materials. The publication further describes that the fabricated target has a density standing at about 90% to about 99% of its theoretical value (which means that a perfect compound target cannot necessarily be obtained), and has an oxygen content standing at about 90% to about 98% of its stoichiometric content (which means that the target is deficient in oxygen). In the cases where other dielectric materials are used, compound targets are fabricated in a similar manner although different powdery raw materials are sintered at different temperatures.

As can be understood from the above publication, in general, a compound target consisting of a plurality of elements is often provided by sintering in which powdery raw materials are mixed and baked. Accordingly, the obtained compound target has a low density and is deficient in oxygen in many cases.

Therefore, in order to compensate for oxygen deficiency in the target when a sputtering process is performed, an oxygen gas is introduced into a chamber to deposit a sputtered film by a sputtering process using a compound target made of, e.g., BSTO, PZTO, SBTO or ITO obtained by sintering. In this manner, a desired sputtered film free from oxygen deficiency is deposited.

However, the generation of particles occurs more often in the use of a method for depositing a sputtered film using the conventional compound target than in the use of a method for depositing a sputtered film using a target consisting of a single element.

### SUMMARY OF THE INVENTION

The present invention has been made to solve the above-described conventional problems and its object is to reduce particles that contaminate a sample when a sputtered film is deposited using a target containing a plurality of elements.

To achieve the above object, according to an inventive method for depositing a sputtered film, a sputtering surface of a target containing a plurality of elements is cleaned by performing a sputtering process at a pressure different from a deposition pressure at which a desired sputtered film is deposited, and a particle preventing film having the same composition as that of the target is deposited, for example, on an inner wall of a chamber by performing the sputtering process within an inert gas ambient.

Specifically, a first inventive sputtered film deposition method is directed to a method for depositing a sputtered film using a target containing a plurality of elements, and includes: a first step of performing in a chamber a sputtering process under a second deposition condition to form at a sputtering surface of the target an erosion area different from that formed under a first deposition condition for depositing the sputtered film; and a second step of depositing the sputtered film on a surface of a sample under the first deposition condition.

According to the first inventive method, the sputtering process in the first step is performed under the second deposition condition to form at the sputtering surface of the target the erosion area different from that formed under the first deposition condition for depositing the desired sputtered film. Thus, it becomes possible to remove deposits attached onto the periphery of the erosion area (erosion track) in the target when the step of depositing the desired sputtered film is repeatedly performed under the first deposition condition. As a result, it becomes possible to prevent the sputtered film on the sample from being contaminated due to the deposits attached onto the target.

In one embodiment of the first inventive method, the second deposition condition preferably includes setting the pressure within the chamber at a value different from that of the pressure of the first deposition condition. In such an embodiment, since the position of the erosion area at the sputtering surface of the target can be shifted, the sputtering surface of the target can be cleaned with certainty.

In this embodiment, the first step preferably includes at least either the step of performing a sputtering process at a pressure higher than that of the first deposition condition, or the step of performing a sputtering process at a pressure lower than that of the first deposition condition.

In another embodiment of the first inventive method, the first step is preferably performed within an inert gas ambient. In such an embodiment, if an oxygen-deficient target, for example, is used, a deposited film attached on an exposed surface inside the chamber is unlikely to peel off. As a result, the particles that contaminate the sample can be reduced.

In this embodiment, the target is preferably made of a metal oxide, and the second step is preferably performed within an oxidizing ambient.

A second inventive sputtered film deposition method is directed to a method for depositing a sputtered film using a target containing a plurality of elements, and includes: a first step of performing a sputtering process within an inert gas ambient, thus depositing a particle preventing film having the same composition as that of the target on an inner wall of a chamber or on an exposed surface of a member provided inside the chamber; and a second step of depositing the sputtered film on a surface of a sample under a predetermined deposition condition.

According to the second inventive method, the particle preventing film having the same composition as that of the target is deposited on the inner wall of the chamber or on the exposed surface of the member provided inside the chamber. Thus, it becomes possible to reduce the particles resulting from the deposits attached onto the inner wall of the chamber or the exposed surface of the member provided inside the chamber.

In one embodiment of the second inventive method, the target is preferably made of a metal oxide, and the second step is preferably performed within an oxidizing ambient.

### BRIEF DESCRIPTION OF THE DRAWINGS

FIGS. 1A through 1C each show a target used in a method for depositing a sputtered film according to the present invention, wherein FIG. 1A is a cross-sectional view of the target in which a first erosion track is formed at a predetermined deposition pressure, FIG. 1B is a cross-sectional view of the target in which a second erosion track is formed at a deposition pressure higher than the predetermined deposition pressure, and FIG. 1C is a cross-sectional view of the target in which a third erosion track is formed at a deposition pressure lower than the predetermined deposition pressure.

FIG. 2 is a schematic cross-sectional view showing a sputtering apparatus that implements the inventive sputtered film deposition method.

### DESCRIPTION OF THE PREFERRED EMBODIMENTS

The present inventors has obtained two findings after thoroughly studied the relationship between conditions for depositing a sputtered film using a target containing a plurality of elements and generation of particles. The obtained two findings are described below.

The first finding is about how a sputtering process is performed. Specifically, we found that if a sputtering process is performed before a desired sputtered film is formed on a sample, with a pressure range in this process set at a value different from that of a pressure at which the desired sputtered film is formed, it becomes possible to reduce particles generated during sputtering.

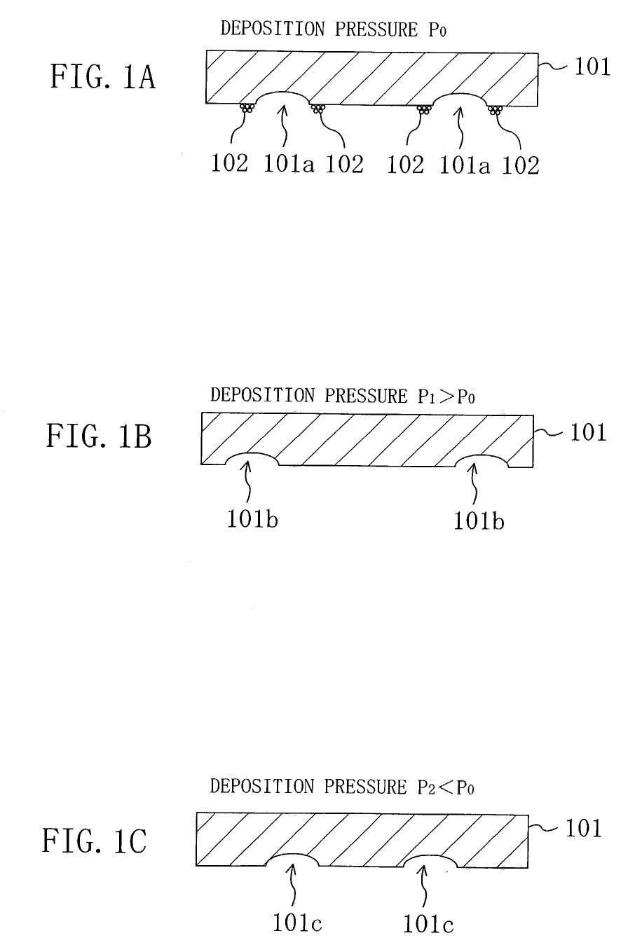

FIG. 1A shows a cross-sectional view of an exemplary magnetron sputtering target containing a plurality of elements when a sputtering process is performed at a deposition pressure at which a desired sputtered film is formed. As shown in FIG. 1A, if a sputtering process is performed at a first deposition pressure P₀ (i.e., under a first deposition condition) set for the deposition of a desired sputtered film, a first erosion track (erosion area) 101a eroded due to the collision of positive ions of argon, for example, is formed at a sputtering surface of a target 101. Furthermore, if a sputtering process is repeatedly performed at the first deposition pressure P₀, deposits 102 are formed on the periphery of the first erosion track 101a by re-sputtered material of the target 101. The deposits 102 peel off and become the cause of generation of the particles that contaminate a sample.

Due to this, as shown in FIG. 1B, if a sputtering process is performed at a second deposition pressure P₁ (i.e., under a second deposition condition) that is higher than the first deposition pressure P₀, a second erosion track 101b is formed at a portion of the target 101 located about 5 mm more outward than the first erosion track 101a formed at the first deposition pressure P₀. In this manner, it becomes possible to remove the outward deposits 102 formed when a sputtering process is performed at a predetermined pressure, i.e., the first deposition pressure P₀.

On the other hand, as shown in FIG. 1C, if a sputtering process is performed at a third deposition pressure P₂ (i.e., under the second deposition condition) that is lower than the first deposition pressure P₀, a third erosion track 101c is formed at a portion of the target 101 located about 5 mm more inward than the first erosion track 101a formed at the first deposition pressure P₀. In this manner, it becomes possible to remove the inward deposits 102 formed when a sputtering process is performed at the first deposition pressure P₀.

As described above, by performing a sputtering process at a deposition pressure within a chamber set higher or lower than the predetermined value before depositing the desired sputtered film on the sample, it becomes possible to remove the deposits 102 on the sputtering surface of the target 101 which are formed by the re-sputtered material of the target 101. Accordingly, it becomes possible to reduce the particles resulting from the deposits 102 on the target 101 containing a plurality of elements.

The second finding is in particular concerning a target made of a sintered metal oxide such as BSTO for use in forming a dielectric film, for example. As already described above, if a current target made of a sintered metal oxide is used, a sputtering process is performed within an oxidizing ambient (i.e., a sputtering process is performed with an oxygen gas added to an argon gas) since the target has an oxygen content smaller than its stoichiometric content.

To the contrary, according to the second finding, by performing a sputtering process using a sputtering gas consisting only of an argon gas without adding an oxygen gas thereto, a particle preventing film having the same composition as that of the oxygen-deficient target is evaporated onto an inner wall of a chamber or an exposed surface of a shield member. We found that the adhesion of the obtained particle preventing film to the inner wall or shield member is higher than that of a desired sputtered film deposited with an oxygen gas added to an argon gas. As used herein, “particle preventing film” refers to a film for preventing the generation of particles that contaminate a sample.

If a sputtering process is performed in this manner, the particle preventing film exhibiting an adhesion higher than that of the desired sputtered film is deposited on the exposed surface inside the chamber. As a result, the deposited film is unlikely to peel off from the exposed surface inside the chamber, thus reducing the particles that contaminate the sample.

### EMBODIMENT

Hereinafter, an embodiment of the present invention will be described with reference to the drawings.

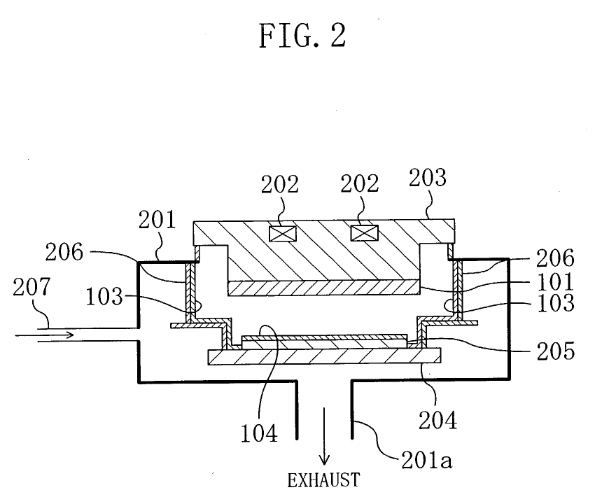

FIG. 2 is a schematic cross-sectional view showing a sputtering apparatus that implements a method for depositing a sputtered film according to the embodiment of the present invention.

As shown in FIG. 2, a chamber 201 is provided at its upper portion with an opening, and a cathode 203 in which magnets 202 are buried is airtightly provided inside the opening.

The chamber 201 is further provided with an outlet 201a and a sample holder 204. The outlet 201a is located at the lower portion of the chamber 201 while the sample holder 204 is located at a certain distance from the outlet 201a. The holder 204 is provided with a heater (not shown) buried therein, and the sample, i.e., a wafer 205, is held on the upper surface of the holder 204. On the surface of the cathode 203 facing the holder 204, a target 101 made of, e.g., a dielectric material, is placed and held.

The target 101 and the upper surface of the holder 204 are covered with a shield member 206 made of, e.g., an aluminum alloy. Therefore, during sputtering, a completely closed space is formed inside the chamber 201 due to the shield member 206. The shield member 206 allows a sputtered film to be evaporated onto the inner wall of the shield member 206 but prevents a sputtered film from being evaporated onto the inner wall of the chamber 201.

The outlet 201a is connected to a cryo pump (not shown), for example, so that a high-vacuum state is maintained in the chamber 201 by exhausting air using the cryo pump.

The chamber 201 is further provided at its sidewall with a gas inlet 207. Through this gas inlet 207, a sputtering gas such as argon, and a reactive gas such as an oxygen (O₂) or nitrogen (N₂) gas are introduced into the chamber 201. After a mixture of the sputtering gas and the reactive gas has been introduced into the chamber 201, a direct-current (DC) voltage or a high frequency (RF) voltage is applied to the cathode 203 to cause plasma discharge inside the chamber 201.

Described below is a method for depositing a sputtered film according to the present embodiment using the sputtering apparatus formed as described above.

(1) Target Cleaning and Particle Preventing Film Depositing Process Step

First, the wafer 205 is held on the holding surface of the holder 204. Then, the inside of the chamber 201 is put into a sufficient vacuum state (<10⁻⁸ Pa) using the cryo pump. Thereafter, only a sputtering gas such as argon is introduced into the chamber 201 through the gas inlet 207. At the same time, a high voltage is applied between the target 101 made of BSTO, for example, and the wafer 205 to sputter the target 101. The deposition pressure in this cleaning process step is set at a value about twice as large as that of the deposition pressure when a desired sputtered film is formed. In this manner, as shown in FIG. 1B, the second erosion track 101b is formed at a relatively outward region of the sputtering surface of the target 101. At the same time, as shown in FIG. 2, the particle preventing film 103 having the substantially same composition as that of the target 101 is deposited at least on the inner wall of the shield member 206. In this embodiment, the thickness of the particle preventing film 103 is about 200 nm. In the target cleaning and particle preventing film depositing process step (hereinafter, called a “process step (1)”), the particle preventing film 103 is also formed on the upper surface of the wafer 205. Therefore, a dummy wafer may be used instead of the wafer 205, or the upper surface of the wafer 205 may be covered. In addition, if a movable shutter mechanism, for example, is provided, it becomes possible to prevent the wafer 205 from being wasted.

(2) Sputtered Film Depositing Process Step

In this process step, since the current target 101 made of BSTO is deficient in oxygen as already mentioned above, an oxygen gas as an active (reactive) gas is added to a sputtering gas. Furthermore, the deposition pressure inside the chamber 201 is reduced to a predetermined deposition pressure at which a desired sputtered film is formed, i.e., a value about half as large as that of the deposition pressure in the process step (1), and then a sputtering process is performed. In this manner, a desired dielectric (sputtered) film 104 made of BSTO, for example, and free from oxygen deficiency is deposited on the upper surface of the wafer 205. In this embodiment, the thickness of the dielectric film 104 is about 30 nm.

According to the present embodiment, before depositing the desired dielectric film 104, a sputtering process is performed using the sputtering surface of the target 101 made of a metal compound such as BSTO (i.e., the target containing a plurality of elements), with the deposition pressure for the sputtering process set at a value different from that of the predetermined deposition pressure as described above. In this manner, an erosion track can be formed at a region of the sputtering surface different from that of the sputtering surface at which the first erosion track 101a is formed under a predetermined deposition condition. As a result, the deposits 102 on the peripheral region of the first erosion track 101a can be removed.

Furthermore, since the sputtering process in the process step (1) is performed using only an inert gas, the particle preventing film 103 whose adhesion to the shield member 206 is higher than that of a deposited film free from oxygen deficiency is formed on the inner wall of the shield member 206. Normally, the deposited film on the shield member 206, for example, is likely to peel off and become the cause of generation of the particles. However, in the present embodiment, the particle preventing film 103 deposited so that oxygen is deficient is unlikely to peel off As a result, the contamination of the wafer 205 can be prevented.

On the other hand, in the sputtered film depositing process step (hereinafter, called a “process step (2)”), an oxygen gas is added to a sputtering gas in order to compensate for oxygen deficiency in the target 101. Therefore, it is possible to prevent an increase in leak current and/or a decrease in capacitance value resulting from oxygen deficiency triggered by using the dielectric film 104 for a capacitor. As a result, the yield of the dielectric film 104 is increased, thus improving the reliability of the resulting semiconductor device in which the dielectric film 104 is used.

Although the particle preventing film 103 is formed to a thickness of about 200 nm, it may be determined in consideration of the total thickness of the particle preventing film 103 with which the generation of the particles might occur. For example, the time of the sputtering process in the process step (1) may be shortened to form the particle preventing film 103 having a thickness of 200 nm or less, and each time the process step (2) has been completed, the process step (1) may be carried out so that the process steps (1) and (2) are repeatedly carried out until the thickness of the particle preventing film 103 exceeds 200 nm.

Furthermore, in the present embodiment, the process step (1) is performed on conditions that the particle preventing film 103 is formed using only an inert gas at a pressure higher than the deposition pressure in the process step (2). However, the present invention is not limited to these conditions. For example, the process step (1) may be effectively performed at a pressure lower than the predetermined deposition pressure depending on the position of the first erosion track 101a with respect to the target 101 and/or the pressure range in the process step (2).

Besides, the process step (1) is performed more effectively if a cleaning step performed at a pressure higher than the predetermined deposition pressure and a cleaning step performed at a pressure lower than the predetermined deposition pressure are repeated for at least one or more cycles.

In the present embodiment, the process step (1), i.e., the target cleaning and particle preventing film depositing process step, is performed as a single process step at a time. Alternatively, the target cleaning and particle preventing film depositing process step may be divided into two steps. Further, if the target cleaning step is performed after the particle preventing film depositing step has been carried out, the sputtering process in the target cleaning step does not necessarily have to be performed within an inert gas ambient. Alternatively, the sputtering process in the target cleaning step may be carried out with an active gas (oxygen gas) added to a sputtering gas.

The sputtering apparatus according to the present embodiment is not limited to a magnetron sputtering apparatus. For example, any sputtering apparatus is effective so long as it can shift the position of the erosion track by performing a sputtering process at the corresponding deposition pressure so that the deposits 102 formed on the sputtering surface of the target 101 are removed.

Moreover, the shield member 206 does not necessarily have to be provided.

In addition, the target 101 containing a plurality of elements is naturally not limited to a target made of BSTO. Any target is particularly effective so long as it is made of a material having an oxygen content smaller than its stoichiometric content.

What is claimed is:

1. A method for depositing a sputtered film using a target containing a plurality of elements, the method comprising:
a first step of performing in a chamber a sputtering process under a second deposition condition to form at a sputtering surface of the target an erosion area different from that formed under a first deposition condition for depositing the sputtered film; and
a second step of depositing the sputtered film on a surface of a sample under the first deposition condition.

2. The method of claim 1, wherein the second deposition condition comprises setting the pressure within the chamber at a value different from that of the pressure of the first deposition condition.

3. The method of claim 2, wherein the first step comprises at least either the step of performing a sputtering process at a pressure higher than that of the first deposition condition, or the step of performing a sputtering process at a pressure lower than that of the first deposition condition.

4. The method of claim 1, wherein the first step is performed within an inert gas ambient.

5. The method of claim 4, wherein the target is made of a metal oxide, and
wherein the second step is performed within an oxidizing ambient.

6. A method for depositing a sputtered film using a target containing a plurality of elements, the method comprising:
a first step of performing a sputtering process within an inert gas ambient, thus depositing a particle preventing film having the same composition as that of the target on an inner wall of a chamber or on an exposed surface of a member provided inside the chamber; and
a second step of depositing the sputtered film on a surface of a sample under a predetermined deposition condition.

7. The method of claim 6, wherein the target is made of a metal oxide, and
wherein the second step is performed within an oxidizing ambient.
